(19) United States
(12) Patent Application Publication
(10) Pub. No.: US 2026/0285881 A1
(43) Pub. Date: Sep. 24, 2026

(54) NIOBIUM FATTY ACID COMPLEX PRODUCTION METHOD AND PIEZOELECTRIC BODY PRODUCTION METHOD

(71) Applicant: SEIKO EPSON CORPORATION, Tokyo (JP)

(72) Inventor: Tsukasa HITOMI, CHINO-SHI (JP)

(21) Appl. No.: 19/574,513

(22) Filed: Mar. 23, 2026

(30) Foreign Application Priority Data
Mar. 24, 2025 (JP) 2025-048748

(51) Int. Cl. C07F 5/00; H10K 85/30

(52) U.S. Cl. CPC C07F 5/003; H10K 85/361

(57) ABSTRACT

A niobium fatty acid complex production method produces a niobium fatty acid complex, the method including: a synthesis step of mixing a fatty acid and a niobium compound to synthesize the niobium fatty acid complex at a first temperature; and a concentration step of concentrating the niobium fatty acid complex under reduced pressure at a second temperature higher than the first temperature. A piezoelectric body production method produces a piezoelectric body containing potassium sodium niobate by using a niobium fatty acid complex, a potassium fatty acid complex, and a sodium fatty acid complex.

The present application is based on, and claims priority from JP Application Serial Number 2025-048748, filed March 24, 2025, the disclosure of which is hereby incorporated by reference herein in its entirety.

### BACKGROUND

### 1. Technical Field

The present disclosure relates to a niobium fatty acid complex production method and a piezoelectric body production method.

### 2. Related Art

A piezoelectric element is used in, for example, a liquid ejection head that ejects a liquid such as ink onto a medium such as printing paper. The piezoelectric element converts a mechanical force into an electric signal, and conversely converts an electric signal into a mechanical force. As a piezoelectric body included in the piezoelectric element, potassium sodium niobate containing K, Na, and Nb ((KₐNa₁₋ₐ)NbO₃) is known. (KₐNa₁₋ₐ)NbO₃ has a perovskite structure represented by the general formula ABO₃ and is abbreviated as KNN.

JP-A-2011-155272 discloses a KNN piezoelectric body using potassium sodium niobate. The KNN piezoelectric body is formed using, for example, a precursor solution containing niobium 2-ethylhexanoate as a metal complex containing Nb.

The present inventors have found that when a niobium fatty acid complex such as niobium 2-ethylhexanoate is used to form a KNN piezoelectric body, there are preferable conditions for the niobium fatty acid complex. Specifically, when the coordination number of 2-ethylhexanoic acid coordinated to niobium is too small, there is a concern that a film formation defect of the piezoelectric body may occur. On the other hand, when the coordination number is too large, a large amount of carbon remains in the piezoelectric body, which may easily cause cracking or easily generate a leakage current.

### SUMMARY

A niobium fatty acid complex production method according to a preferred aspect of the present disclosure is a production method for producing a niobium fatty acid complex, the method including: a synthesis step of mixing a fatty acid and a niobium compound to synthesize a niobium fatty acid complex at a first temperature; and a concentration step of concentrating the niobium fatty acid complex under reduced pressure at a second temperature higher than the first temperature.

A piezoelectric body production method according to a preferred aspect of the present disclosure produces a piezoelectric body containing potassium sodium niobate using a niobium fatty acid complex, a potassium fatty acid complex, and a sodium fatty acid complex.

### BRIEF DESCRIPTION OF THE DRAWINGS

FIG. 1 is a schematic view illustrating a configuration of a liquid ejection device according to a first embodiment.

FIG. 2 is an exploded perspective view of a liquid ejection head illustrated in FIG. 1.

FIG. 3 is a cross-sectional view of a part of the liquid ejection head illustrated in FIG. 2.

FIG. 4 is a view illustrating a diaphragm and a piezoelectric element of FIG. 3.

FIG. 5 is a flowchart showing a piezoelectric body production method according to the first embodiment.

FIG. 6 is a flow chart showing a niobium fatty acid complex production method according to the first embodiment.

FIGS. 7A to 7C are diagrams showing examples of reaction formulae in the synthesis step of FIG. 6.

FIGS. 8A to 8C are diagrams showing a niobium compound and a niobium fatty acid complex in the niobium fatty acid complex production method of FIG. 6.

FIG. 9 is a table showing Examples and Comparative Examples.

### DESCRIPTION OF EMBODIMENTS

Preferred embodiments according to the present disclosure will be described with reference to the accompanying drawings. In the drawings, dimensions or scales of respective members are different from the actual dimensions or scales as appropriate, and some members are schematically illustrated for easy understanding. In addition, the scope of the present disclosure is not limited to these embodiments unless it is noted in the following description that the present disclosure is particularly limited. The phrase "the element α and the element β are stacked" means that the element α and the element β need only be arranged in an up-down direction, and whether the element α and the element β are in direct contact with each other is not a problem.

The following description will be made by using an X axis, a Y axis, and a Z axis that intersect each other, as appropriate. One direction along an X axis will be referred to as an X1 direction, and a direction opposite to the X1 direction will be referred to as an X2 direction. Directions opposite to each other along the Y axis will be referred to as a Y1 direction and a Y2 direction. Directions opposite to each other along the Z axis will be referred to as a Z1 direction and a Z2 direction. Viewing in a direction along the Z axis will be referred to as a "plan view." The Z axis is typically a vertical axis. The Z1 direction is an upper side, and the Z2 direction is a lower side. However, the Z axis does not need to be a vertical axis. The X axis, the Y axis, and the Z axis are typically orthogonal to each other, but are not limited thereto, and need only intersect each other at an angle within a range of from, for example, 80° to 100°.

### 1. First Embodiment

### 1-1. Overall Configuration of Liquid Ejection Device 100

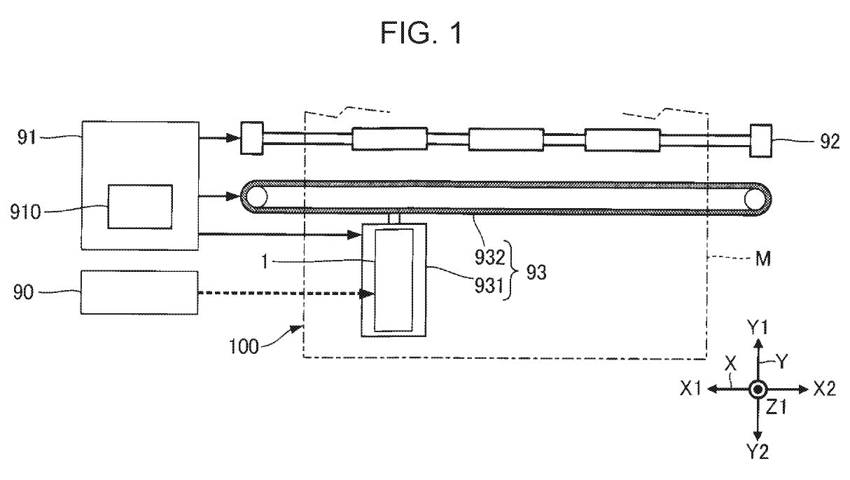

FIG. 1 is a configuration diagram schematically illustrating a liquid ejection device 100 according to a first embodiment. The liquid ejection device 100 is an ink jet printing apparatus that ejects ink, which is an example of liquid, to a medium M as liquid droplets. The medium M is typically printing paper. The medium M is not limited to printing paper and may be, for example, a printing target of any material such as a resin film or a cloth.

As illustrated in FIG. 1, the liquid ejection device 100 is equipped with a liquid container 90 for storing the ink. Examples of specific forms of the liquid container 90 include a cartridge that can be attached to and detached from the liquid ejection device 100, a bag-shaped ink pack formed of a flexible film, and an ink tank that can be refilled with the ink. A type of the ink stored in the liquid container 90 is optional. The "liquid" may be any material that can be discharged from the liquid ejection device 100. For example, the "liquid" may be a material in which a solid material is contained in a liquid.

The liquid ejection device 100 includes a controller 91, a transport mechanism 92, a moving mechanism 93, and a liquid ejection head 1. The controller 91 includes, for example, a processing circuit such as a central processing unit (CPU) or a field programmable gate array (FPGA) and a storage circuit such as a semiconductor memory, and controls the operation of each element of the liquid ejection device 100. The controller 91 includes a voltage application circuit 910 which causes the ink to be ejected from a nozzle by controlling the driving of a piezoelectric element 5 which will be described later. The voltage application circuit 910 applies a reference voltage VBS and a driving voltage Com to the piezoelectric element 5, which will be described later, included in the liquid ejection head 1.

The transport mechanism 92 transports the medium M in the Y2 direction under the control of the controller 91. The moving mechanism 93 reciprocates the liquid ejection head 1 in the X1 direction and the X2 direction under the control of the controller 91. In the example illustrated in FIG. 1, the moving mechanism 93 includes a substantially box-shaped transport body 931 called a carriage that accommodates the liquid ejection head 1, and a transport belt 932 to which the transport body 931 is fixed. The number of liquid ejection heads 1 mounted on the transport body 931 is not limited to one, and may be two or more. The liquid container 90 may be mounted on the transport body 931 in addition to the liquid ejection head 1.

The liquid ejection head 1 ejects the ink supplied from the liquid containers 90 onto the medium M in the Z2 direction from each of multiple nozzles under the control of the controller 91. The liquid ejection head 1 includes a plurality of piezoelectric elements 5 for ejecting ink from a plurality of nozzles N, which will be described later. The ejection is performed in parallel with the transport of the medium M via the transport mechanism 92 and the reciprocating movement of the liquid ejection head 1 via the moving mechanism 93, so that an image is formed by the ink on a surface of the medium M.

### 1-2. Overall Configuration of Liquid Ejection Head 1

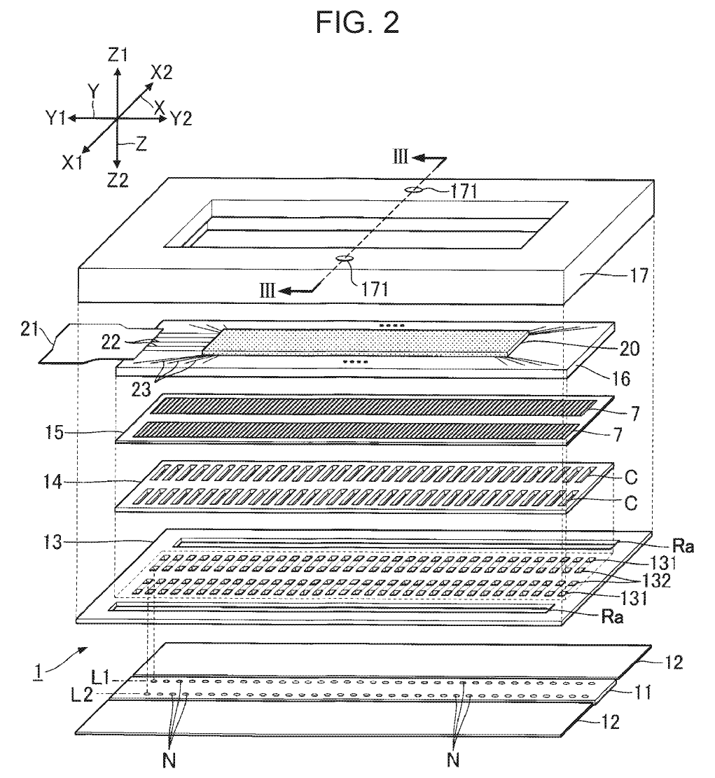

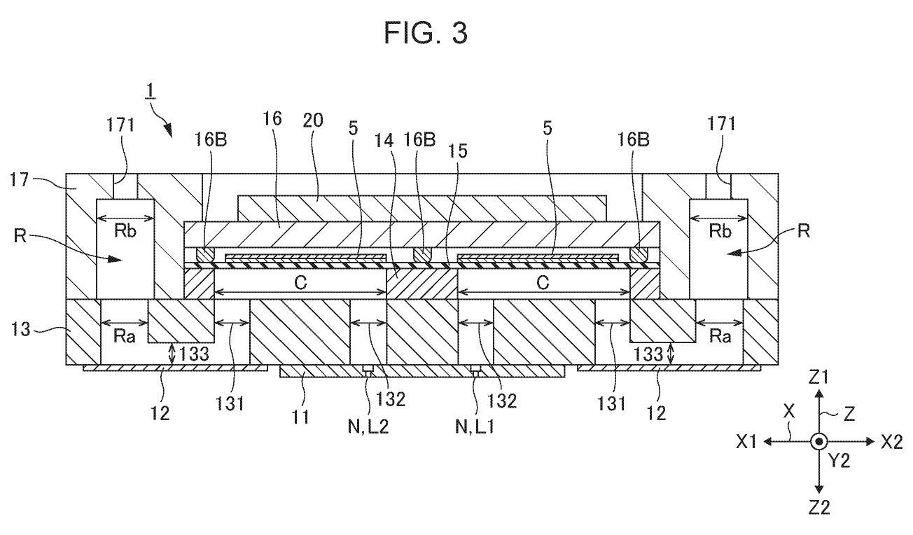

FIG. 2 is an exploded perspective view of the liquid ejection head 1 illustrated in FIG. 1. FIG. 3 is a cross-sectional view of a part of the liquid ejection head 1 illustrated in FIG. 2, and is a cross-sectional view taken along the line III-III in FIG. 2.

As illustrated in FIG. 2, the liquid ejection head 1 includes the plurality of nozzles N arranged in a direction along the Y axis. In the example illustrated in FIG. 2, the nozzles N are divided into a first row L1 and a second row L2 arranged at an interval in the direction along the X axis. Each of the first row L1 and the second row L2 is a set of the plurality of nozzles N linearly arranged in the direction along the Y axis. An element related to each nozzle N in the first row L1 and an element related to each nozzle N in the second row L2 in the liquid ejection head 1 are substantially symmetrical with each other in the direction along the X axis. In the following description, the element corresponding to the first row L1 will be mainly described, and the description of the element corresponding to the second row L2 will be omitted as appropriate.

The positions of the nozzles N in the first row L1 and the positions of the nozzles N in the second row L2 in the direction along the Y axis may be the same as one another or may be different from one another. In addition, the element related to the nozzles N in one of the first row L1 and the second row L2 may be omitted.

As illustrated in FIGS. 2 and 3, the liquid ejection head 1 includes a nozzle plate 11, a vibration absorber 12, a flow path substrate 13, a pressure chamber substrate 14, a diaphragm 15, a wiring substrate 16, a housing 17, and a driving circuit 20. Each of the nozzle plate 11, the vibration absorber 12, the flow path substrate 13, the pressure chamber substrate 14, the diaphragm 15, the wiring substrate 16, and the housing 17 is a plate-shaped member that is elongated in the direction along the Y axis. The nozzle plate 11, the flow path substrate 13, the pressure chamber substrate 14, the diaphragm 15, and the wiring substrate 16 are arranged in this order in the Z1 direction.

The nozzle plate 11 is a plate-shaped member in which the plurality of nozzles N are formed. Each of the nozzles N is a circular through-hole through which the ink passes. The nozzles N eject the ink by the vibration of the diaphragm 15. The nozzle plate 11 is bonded to the flow path substrate 13 using, for example, an adhesive. The nozzles N are sites from which the liquid is ejected by the pressure applied in a pressure chamber C.

The flow path substrate 13 is formed with a flow path for supplying the ink to the plurality of nozzles N. Specifically, in the flow path substrate 13, a space Ra, a plurality of supply flow paths 131, a plurality of communication flow paths 132, and a supply liquid chamber 133 are formed. The space Ra is an elongated opening extending in the direction along the Y axis in a plan view when viewed in the direction along the Z axis. Each of the supply flow paths 131 and the communication flow paths 132 is a through-hole formed for each nozzle N. The supply liquid chamber 133 is an elongated space extending in the direction along the Y axis over the plurality of nozzles N, and allows the space Ra and the plurality of supply flow paths 131 to communicate with each other. Each of the communication flow paths 132 overlaps one nozzle N corresponding to the communication flow path 132 in a plan view. The pressure chamber substrate 14 is bonded to the flow path substrate 13 using, for example, an adhesive.

In the pressure chamber substrate 14, a plurality of pressure chambers C is provided. The plurality of pressure chambers C is arranged in the direction along the Y axis. Each pressure chamber C is formed for each nozzle N, and is an elongated space extending in the direction along the X axis in a plan view. The pressure chambers C are spaces located between the flow path substrate 13 and the diaphragm 15. The pressure chambers C communicate with the nozzles N via the communication flow paths 132 and communicate with the space Ra via the supply flow paths 131 and the supply liquid chamber 133. The pressure chambers C are portions through which the liquid flows and in which a pressure is applied to the liquid by the piezoelectric element 5.

Each of the nozzle plate 11, the flow path substrate 13, and the pressure chamber substrate 14 is manufactured by processing a silicon single crystal substrate by using dry etching, wet etching, or the like, for example. However, other known methods may be used as appropriate for manufacturing each of the nozzle plate 11, the flow path substrate 13, and the pressure chamber substrate 14.

The diaphragm 15 is disposed on a surface of the pressure chamber substrate 14 facing the Z1 direction. The diaphragm 15 is a plate-shaped member that can elastically vibrate.

The plurality of piezoelectric elements 5 corresponding to the nozzles N is disposed on a surface of the diaphragm 15 facing the Z1 direction. Each piezoelectric element 5 has an elongated shape extending in the direction along the X axis in a plan view. The plurality of piezoelectric elements 5 corresponds to the plurality of pressure chambers C, and is arranged in the direction along the Y axis. The piezoelectric elements 5 are deformed by application of a voltage. When the diaphragm 15 vibrates in conjunction with the deformation, the pressure in the pressure chambers C fluctuates, so that the ink is ejected from the nozzles N.

The housing 17 is a case for storing the ink supplied to the plurality of pressure chambers C. As illustrated in FIG. 3, a space Rb is formed in the housing 17. The space Rb of the housing 17 and the space Ra of the flow path substrate 13 communicate with each other. A space formed by the space Ra and the space Rb functions as a liquid storage chamber R that is a reservoir that stores the ink supplied to the plurality of pressure chambers C. The ink is supplied to the liquid storage chamber R through an inlet 171 formed in the housing 17. The ink in the liquid storage chamber R is supplied to the pressure chamber C through the supply liquid chamber 133 and each supply flow path 131.

The vibration absorber 12 is a flexible film that forms a wall surface of the liquid storage chamber R. The vibration absorber 12 is a compliance substrate that absorbs fluctuation in the pressure of the ink in the liquid storage chamber R.

The wiring substrate 16 is a plate-shaped member on which wiring for electrically coupling the driving circuit 20 and the plurality of piezoelectric elements 5 is formed. A surface of the wiring substrate 16 facing the Z2 direction is bonded to the diaphragm 15 via a plurality of conductive bumps 16B. On the other hand, the driving circuit 20 is mounted on a surface of the wiring substrate 16 facing the Z1 direction. The driving circuit 20 is an integrated circuit (IC) chip that outputs the driving voltage Com and the reference voltage VBS for driving each piezoelectric element 5.

As illustrated in FIG. 2, an end portion of external wiring 21 is bonded to a surface of the wiring substrate 16 facing the Z1 direction. The external wiring 21 is configured by, for example, a coupling component such as a flexible printed circuit (FPC), a flexible flat cable (FFC), or the like. The wiring substrate 16 is formed with a plurality of wires 22 that electrically couple the external wiring 21 and the driving circuit 20, and a plurality of wires 23 to which the driving voltage Com and the reference voltage VBS output from the driving circuit 20 are supplied.

The wiring substrate 16 is not limited to a rigid substrate, and may be, for example, a flexible printed circuit (FPC) or a flexible flat cable (FFC). In this case, the wiring substrate 16 may also serve as the external wiring 21.

In the liquid ejection head 1, when the piezoelectric elements 5 are bent and deformed by application of a voltage, the diaphragm 15 is bent and deformed, that is, vibrates in a direction in which volumes of the pressure chambers C decrease. As a result, the pressure of the pressure chambers C changes, and the ink in the pressure chambers C is ejected from the nozzles N. After the ink ejection, the piezoelectric elements 5 are restored to the original positions thereof.

The liquid ejection head 1 includes the piezoelectric elements 5, the pressure chambers C through which liquid ink flows and in which pressure is applied to the ink by the piezoelectric elements 5, and the nozzles N from which the ink is ejected by the pressure applied in the pressure chambers C. According to the liquid ejection head 1, since the piezoelectric elements 5 having characteristics to be described later are provided, a leakage current can be prevented from being generated. Therefore, the liquid ejection head 1 having excellent quality can be provided.

In addition, the liquid ejection head 1 includes all of the elements illustrated in FIG. 3, but the constituent elements of the liquid ejection head 1 may not include all of the elements or may further include an additional element.

### 1-3. Diaphragm 15 and Piezoelectric Element 5

FIG. 4 is a cross-sectional view illustrating the diaphragm 15 and one of the piezoelectric elements 5 of FIG. 3. In the example illustrated in FIG. 4, the diaphragm 15 is formed of a stacked body including a first vibrating body layer 151 and a second vibrating body layer 152. The first vibrating body layer 151 is in contact with the pressure chamber substrate 14. The second vibrating body layer 152 is disposed above the first vibrating body layer 151. The first vibrating body layer 151 is formed of an elastic material such as silicon oxide (SiOₓ). The second vibrating body layer 152 is formed of an insulating material such as zirconium oxide (ZrOₓ). The first vibrating body layer 151 is formed by, for example, thermally oxidizing a portion of the pressure chamber substrate 14. The second vibrating body layer 152 is formed by, for example, a known film forming technique such as sputtering. The diaphragm 15 may include one layer or may include three or more layers.

The piezoelectric element 5 is provided on the diaphragm 15. The piezoelectric element 5 mainly includes a lower electrode 51, a piezoelectric layer 53, an upper electrode 52, and a seed layer 54. The lower electrode 51, the seed layer 54, the piezoelectric layer 53, and the upper electrode 52 are provided in this order along the Z2 direction, which is the stacking direction.

The lower electrode 51 is provided above the diaphragm 15. The lower electrode 51 is an individual electrode provided for each piezoelectric element 5. A variable driving voltage Com is applied to the lower electrode 51. The lower electrode 51 has an elongated shape along the X axis. A plurality of lower electrodes 51 is arranged at an interval from each other along the Y axis. The lower electrode 51 includes a conductive material such as platinum (Pt), for example. The thicknesses of the lower electrode 51 along the Z axis is not particularly limited, and is, for example, 50 nm or more and 120 nm or less. The lower electrode 51 may be formed of a single layer or a plurality of layers. The lower electrode 51 is formed using a sputtering method.

The seed layer 54 is provided to control the orientation of the piezoelectric layer 53. The thickness of the seed layer 54 along the Z axis is smaller than the thickness of the piezoelectric layer 53 along the Z axis. The thickness of the seed layer 54 along the Z axis is not particularly limited, but is, for example, 5 nm or more and 50 nm or less. The seed layer 54 may be formed of a single layer or a plurality of layers. The seed layer 54 is formed using a sputtering method or a solution method.

For example, the seed layer 54 has a perovskite structure. The seed layer 54 includes, for example, lead titanate PbₐTi_{b}O_{z}, lanthanum nickelate LaₐNi_{b}O_{z}, PbₓBi₍ₐ₋ₓ₎Fe_{y}Ti_{(b-y)}O_{z}, BiₐFe_{y}Ti_{(b-y)}O_{z}, or PbₐFe_{y}Ti_{(b-y)}O_{z}. In the above chemical formula, it is necessary to satisfy 0 < x < a and 0 < y < b. The seed layer 54 may contain a composite oxide having a perovskite structure containing Bi, Fe, and Ti. In particular, the seed layer 54 preferably includes PbₓBi₍ₐ₋ₓ₎Fe_{y}Ti_{(b-y)}O_{z}. PbₓBi₍ₐ₋ₓ₎Fe_{y}Ti_{(b-y)}O_{z} is particularly preferable because of excellent orientation controllability.

The piezoelectric layer 53 is, for example, a band-shaped dielectric film that is continuous along the Y axis over the plurality of piezoelectric elements 5. The piezoelectric layer 53 has, for example, a band shape extending along the Y axis, and is divided into each piezoelectric element 5 by a plurality of cutouts being formed. The thickness of the piezoelectric layer 53 along the Z axis is not particularly limited, and is, for example, 300 nm or more and 1500 nm or less.

The piezoelectric layer 53 contains K, Na, and Nb. Specifically, the piezoelectric material constituting the piezoelectric layer 53 has a perovskite structure containing K and Na at A sites and Nb at B sites. Specifically, the piezoelectric material includes a composite oxide containing potassium sodium niobate ((KₐNa₁₋ₐ)NbO₃). (KₐNa₁₋ₐ)NbO₃ has a perovskite structure represented by the general formula ABO₃ and is abbreviated as KNN. Therefore, the piezoelectric material includes a KNN-based composite oxide. The symbol "a" satisfies 0.1 ≤ a ≤ 0.9.

Since the KNN-based composite oxide is a lead-free piezoelectric material in which the content of lead (Pb) and the like is suppressed, the KNN-based composite oxide has excellent biocompatibility and a small environmental load. In addition, since the KNN-based composite oxide has excellent piezoelectric properties among lead-free piezoelectric materials, the KNN-based composite oxide is advantageous in improving various properties.

In the piezoelectric material, for example, a metal element other than Nb may be contained as an additive in a A site or a B site of potassium sodium niobate. Examples of the additive include manganese (Mn), lithium (Li), barium (Ba), calcium (Ca), strontium (Sr), zirconium (Zr), titanium (Ti), bismuth (Bi), tantalum (Ta), antimony (Sb), iron (Fe), cobalt (Co), silver (Ag), magnesium (Mg), zinc (Zn), and copper (Cu). Note that the metal element added may be one kind or plural kinds.

In addition, the piezoelectric material constituting the piezoelectric layer 53 may be a mixed crystal of the KNN-based composite oxide and another composite oxide having a perovskite structure represented by ABO₃.

The piezoelectric layer 53 is manufactured by, for example, a solution method such as a metal organic decomposition (MOD) method or a sol-gel method. The sol-gel method is a method in which a precursor solution made of sol is applied to a lower layer to form a piezoelectric precursor film, and then the piezoelectric precursor film is dried at a predetermined temperature to be degreased. The MOD method is a method of applying an MOD solution to a lower layer, followed by drying and degreasing.

The piezoelectric layer 53 may be formed of a plurality of layers or a single layer.

The upper electrode 52 is provided above the piezoelectric layer 53. The upper electrode 52 is a band-shaped common electrode extending along the Y axis so as to be continuous over the plurality of piezoelectric elements 5. A predetermined reference voltage VBS is applied to the upper electrode 52. The upper electrode 52 contains a conductive material such as iridium (Ir), for example. The thickness of the upper electrode 52 along the Z axis is not particularly limited, and is, for example, 50 nm or more and 120 nm or less. The upper electrode 52 may be formed of a single layer or a plurality of layers. The upper electrode 52 is formed using a sputtering method.

In the piezoelectric element 5, a voltage corresponding to a difference between the reference voltage VBS applied to the upper electrode 52 and the driving voltage Com corresponding to the ejection amount supplied to the lower electrode 51 is applied to the piezoelectric layer 53. By applying a voltage between the lower electrode 51 and the upper electrode 52, the piezoelectric layer 53 deforms such that the piezoelectric element 5 is bent and deformed, that is, vibrates.

Although the lower electrode 51 is an individual electrode and the upper electrode 52 is a common electrode in the present embodiment, the lower electrode 51 may be a common electrode and the upper electrode 52 may be an individual electrode.

### 1-4. Method of Producing Piezoelectric Layer 53

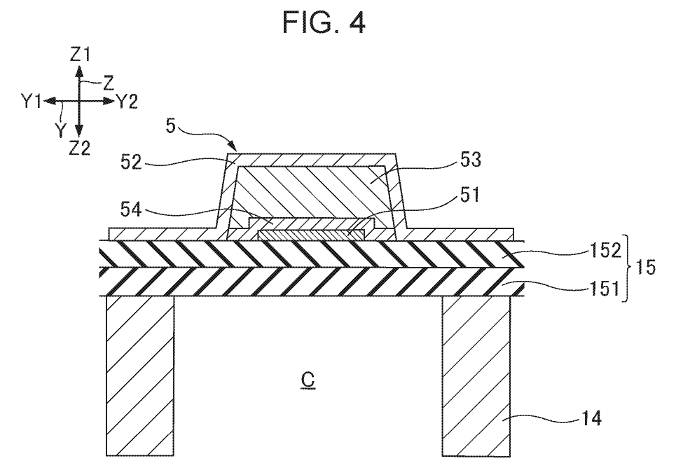

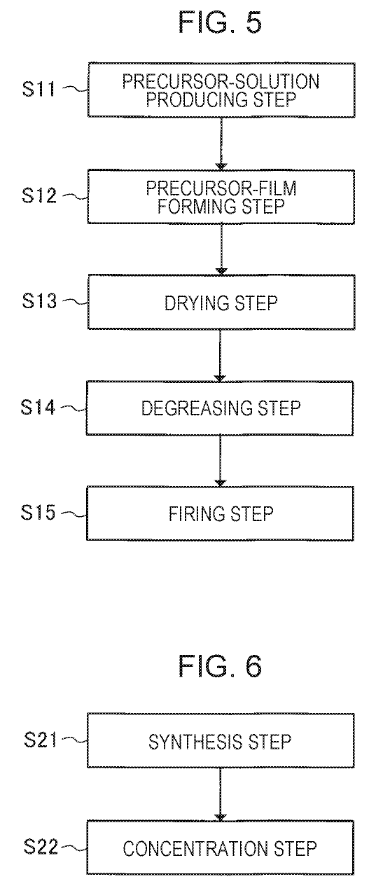

FIG. 5 is a flowchart showing a method of producing the piezoelectric layer 53 of the first embodiment. A piezoelectric body production method will be described below using a method of producing the piezoelectric layer 53 formed above the lower electrode 51 and the seed layer 54 as an example.

As shown in FIG. 5, the method of producing the piezoelectric layer 53 includes a precursor-solution producing step S11, a precursor-film forming step S12, a drying step S13, a degreasing step S14, and a firing step S15 in this order.

In the precursor-solution producing step S11, a precursor-solution containing a niobium fatty acid complex, a potassium fatty acid complex, and a sodium fatty acid complex is produced. The precursor solution is produced by dissolving or dispersing the niobium fatty acid complex, potassium fatty acid complex, and sodium fatty acid complex in an organic solvent. The precursor solution may contain a metal complex other than the niobium fatty acid complex, potassium fatty acid complex, and sodium fatty acid complex. For example, an additive such as Mn may be contained. Examples of the solvent include 2-n-butoxyethanol, N-octane, and a mixed solvent thereof. The precursor solution may further contain another component. In the present embodiment, niobium 2-ethylhexanoate, potassium 2-ethylhexanoate, and sodium 2-ethylhexanoate are used, but another niobium fatty acid complex, potassium fatty acid complex, and sodium fatty acid complex may be used. However, in consideration of the reaction efficiency, the fatty acids constituting the niobium fatty acid complex, potassium fatty acid complex, and sodium fatty acid complex are preferably the same. In addition, the fatty acid more preferably has 2 or more and 12 or less carbon atoms. Since potassium 2-ethylhexanoate and sodium 2-ethylhexanoate are excellent from the viewpoints of high purity, cost, and the like, FIG. 6 only describes a method for producing niobium 2-ethylhexanoate with the combination of potassium 2-ethylhexanoate and sodium 2-ethylhexanoate as described below.

In the precursor-film forming step S12, a precursor film is formed by applying a precursor solution from above the lower electrodes 51 and the seed layer 54. In the drying step S13, the precursor film is dried at a predetermined temperature for a certain time. The predetermined temperature is, for example, 130°C or more and 250°C or less.

In the degreasing step S14, the dried precursor film is held at a predetermined temperature for a certain time at a temperature higher than that in the drying step S13. The predetermined temperature is, for example, 300°C or more and 450°C or less.

In the firing step S15, the degreased precursor film is held at a predetermined temperature for a certain time at a temperature higher than that in the degreasing step S14. The predetermined temperature is, for example, 650°C or more and 800°C or less. Through the firing step S15, niobium 2-ethylhexanoate, potassium 2-ethylhexanoate, and sodium 2-ethylhexanoate are crystallized, and the piezoelectric layer 53 which is a piezoelectric body containing potassium sodium niobate is formed.

Heating in each of the drying step S13, the degreasing step S14, and the firing step S15 is performed using, for example, an infrared lamp or a hot plate. When the piezoelectric layer 53 is composed of a plurality of layers, the drying step S13, the degreasing step S14, and the firing step S15 are performed for each layer. After the drying step S13 and the degreasing step S14 are performed for each layer, the firing step S15 may be collectively performed for all the layers.

As described above, in the piezoelectric body production method, the piezoelectric body containing potassium sodium niobate is produced using niobium 2-ethylhexanoate, potassium 2-ethylhexanoate, and sodium 2-ethylhexanoate. Since niobium 2-ethylhexanoate serving as a raw material has the characteristics described below, the risk of cracking in the piezoelectric body can be reduced while reducing film formation defects in the production of the piezoelectric body.

### 1-5. Niobium Fatty Acid Complex Production Method

FIG. 6 is a flow chart showing the method of producing niobium 2-ethylhexanoate according to the first embodiment. As shown in FIG. 6, the method of producing niobium 2-ethylhexanoate includes a synthesis step S21 and a concentration step S22 in this order. As described above, another niobium fatty acid complex may be produced by this method instead of niobium 2-ethylhexanoate.

In the synthesis step S21, raw materials and a solvent are mixed to produce a raw material solution, and then the raw material solution is heated at a first temperature. In this step, niobium 2-ethylhexanoate having a relatively large coordination number of 2-ethylhexanoic acid coordinated to niobium (hereinafter, also simply referred to as the coordination number of niobium 2-ethylhexanoate) is synthesized.

In the production of a raw material solution, raw materials and the like are subjected to a dehydrating and deoxidizing treatment, and then raw materials to be used for synthesis are weighed and mixed. Examples of the raw materials and the like include 2-ethylhexanoic acid, toluene, and acetic anhydride. Toluene serves as the solvent. A solvent other than toluene may be used. Acetic anhydride is also a reactant used to decompose or consume ethanol and water which are by-products in the synthesis. A reactant other than acetic anhydride may be used. When another fatty acid complex is produced instead of 2-ethylhexanoic acid complex, the fatty acid as a raw material is a carboxylic acid having a carboxy group in the hydrocarbon chain, and examples thereof include 2-ethylpentanoic acid and 2-methylpentanoic acid.

To be specific, for example, in the synthesis step S21, a synthetic zeolite called a molecular sieve is added to the above-mentioned raw materials and the like, and a dehydrating and deoxidizing treatment is performed by a bubbling method in which nitrogen gas is fed for a predetermined time. Thereafter, in an argon atmosphere, 2-ethylhexanoic acid, toluene, and acetic anhydride are weighed and mixed, and then a niobium compound is added. By this treatment, a raw material solution of the niobium fatty acid complex can be obtained.

The niobium compound is an organometallic compound of Nb except for niobium fatty acid compounds. Therefore, the niobium compound is an organometallic compound of Nb having no carboxyl group. For example, the niobium compound is an organometallic compound of Nb having an alkoxy group. More specifically, the niobium compound may be any compound as long as it reacts with 2-ethylhexanoic acid and acetic anhydride to produce niobium 2-ethylhexanoate when the above materials are mixed. Specific examples thereof include pentaethoxyniobium and pentamethoxyniobium.

Next, the raw material solution is heated at the first temperature to synthesize niobium 2-ethylhexanoate. Specifically, for example, the raw material solution is heated to the first temperature and stirred for a predetermined time under a nitrogen flow. For example, silicone oil is used as a heating medium. By stirring the raw material solution at the first temperature for a predetermined time, ligands of the niobium compound is substituted with a fatty acid group. As a result, niobium 2-ethylhexanoate is produced.

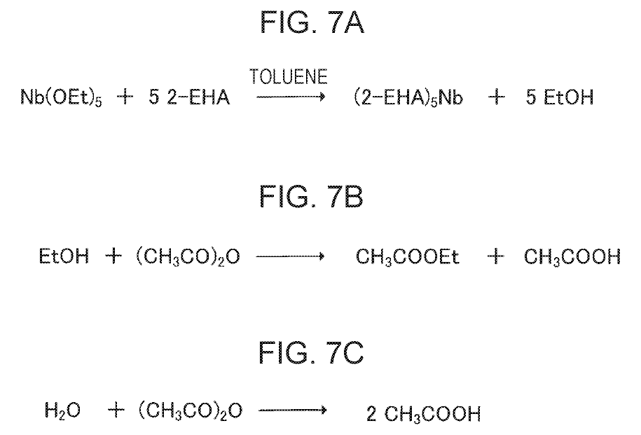

FIGS. 7A to 7C are diagrams showing reaction formulae of a reaction expected to occur in the synthesis step S21 in FIG. 6. Note that in FIGS. 7A to 7C, substances are represented by simplified abbreviations.

FIG. 7A shows a synthesis reaction between pentaethoxyniobium (Nb(OEt)₅) as a niobium compound and 2-ethylhexanoic acid (2-EHA). Niobium 2-ethylhexanoate (2-EHA)₅Nb and ethanol (EtOH) are produced from pentaethoxyniobium (Nb(OEt)₅) and 2-ethylhexanoic acid (2-EHA). In this synthesis, toluene is used as the solvent.

In each of FIGS. 7B and 7C, side reactions in the synthesis in FIG. 7A are shown. Ethyl acetate (CH₃COOEt) and acetic acid (CH₃COOH) are produced from ethanol and acetic anhydride ((CH₃CO)₂O) which are by-products produced in the synthesis in FIG. 7A. In addition, a trace amount of water is produced in the synthesis in FIG. 7A and the side reaction in FIG. 7B. In the side reaction shown in FIG. 7C, acetic acid is produced from water (H₂O) and acetic anhydride.

In the concentration step S22, niobium 2-ethylhexanoate is concentrated under reduced pressure at a second temperature higher than the first temperature. Specifically, niobium 2-ethylhexanoate is concentrated at the second temperature under reduced pressure, and after gas generation is no longer observed, vacuum drying is performed for a predetermined time. For example, silicone oil is used as a heating medium. Through the above steps, liquid niobium 2-ethylhexanoate is produced.

In the concentration step S22, some of the ligands of niobium 2-ethylhexanoate are eliminated. As a result, the coordination number of 2-ethylhexanoic acid coordinated to niobium after the concentration step S22 is smaller than the coordination number of 2-ethylhexanoic acid coordinated to niobium before the concentration step S22. As a presumed mechanism, this is considered to be because one or more ligands among the plurality of ligands are eliminated in the concentration step S22, and after the elimination of the ligands, a remaining ligand occupies the vacant coordination site through bidentate coordination to stabilize the complex.

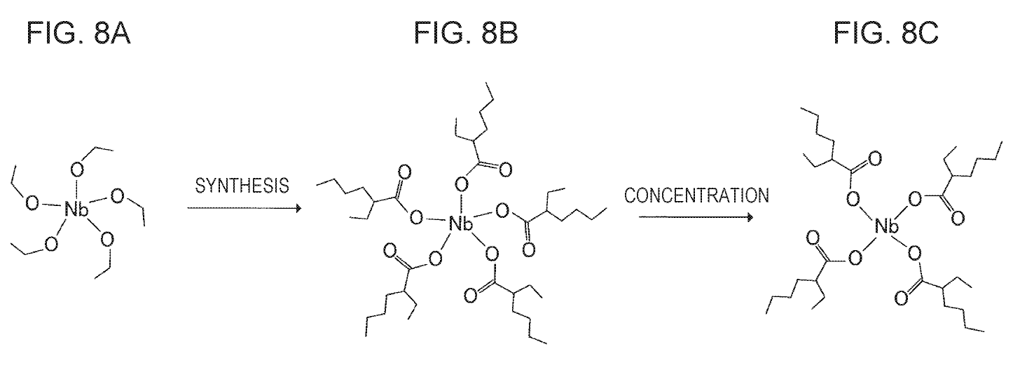

FIGS. 8A to 8C are diagrams showing a niobium compound and niobium 2-ethylhexanoate in the method of producing niobium 2-ethylhexanoate of FIG. 6. FIG. 8A shows pentaethoxyniobium as an example of the niobium compound. FIG. 8B shows niobium 2-ethylhexanoate after the synthesis step S21 and before the concentration step S22 as an example. In the example shown in FIG. 8B, ethoxy groups of pentaethoxyniobium are substituted with 2-ethylhexane groups. The coordination number of niobium 2-ethylhexanoate shown in FIG. 8B is 5. FIG. 8C shows niobium 2-ethylhexanoate after the concentration step S22 as an example. The coordination number of niobium 2-ethylhexanoate shown in FIG. 8C is 4.

As described above, niobium 2-ethylhexanoate is produced through the synthesis step S21 and the concentration step S22 in the production method. The synthesis step S21 is a step of mixing 2-ethylhexanoic acid and the niobium compound to synthesize a niobium fatty acid complex at the first temperature. The concentration step S22 is a step of concentrating niobium 2-ethylhexanoate under reduced pressure at the second temperature higher than the first temperature.

By performing the synthesis at the first temperature, which is a relatively low temperature, the coordination number of fatty acids coordinated to niobium can be increased. In addition, the variation in the coordination number of the plurality of niobium 2-ethylhexanoate complexes present in the solution can be reduced.

When a KNN piezoelectric body is formed using a niobium compound, the niobium compound has high reactivity and starts to decompose during film formation of the KNN piezoelectric body. For this reason, it is difficult to form a homogeneous NKK piezoelectric body, and there is a concern that film formation defects may occur. In contrast, niobium 2-ethylhexanoate obtained through the synthesis step S21 is more stable than the niobium compound. Therefore, the use of niobium 2-ethylhexanoate can reduce the film formation defects.

However, when the stability is too high, in the formation of the KNN piezoelectric body, the amount of carbon of 2-ethylhexanoic acid as a ligand is too large, that is, carbon remains, and there is a concern that cracks may occur in the piezoelectric body due to the presence of the ligand thereof. When cracks are easily generated, a leakage current may be easily generated. For this reason, the coordination number of niobium 2-ethylhexanoate is preferably reduced to some extent.

As described above, the coordination number of niobium 2-ethylhexanoate can be reduced by performing the concentration under reduced pressure at the second temperature higher than the first temperature. Furthermore, the variation in the coordination number of niobium 2-ethylhexanoate can be reduced. That is, the variation in the coordination number of niobium 2-ethylhexanoate in a solution containing the plurality of niobium 2-ethylhexanoate complexes in a liquid state, that is, a dispersion liquid obtained through the concentration step S22 can be reduced. For this reason, by using the precursor solution containing the dispersion liquid, the risk of occurrence of film formation defects can be reduced.

As described above, when the method of producing niobium 2-ethylhexanoate includes the synthesis step S21 and the concentration step S22, niobium 2-ethylhexanoate having a coordination number suitable for suppressing film formation defects and generation of a leakage current in the KNN piezoelectric body.

Further, the coordination number can be suitably controlled by adjusting the second temperature. Specifically, the second temperature is preferably higher than 100°C. When the second temperature is higher than 100°C, the coordination numbers can be suitably reduced through the concentration step S22. Specifically, for example, when the coordination number exceeds 5 due to the synthesis, the coordination number can be reduced to 5.0 or less through the concentration step S22. Since the coordination number can be reduced, generation of the above-described leakage current can be effectively suppressed.

Further, the second temperature is preferably higher than 120°C. When the second temperature is higher than 120°C, the coordination number can be more suitably reduced through the concentration step S22. Specifically, for example, when the coordination number exceeds 5 due to the synthesis, the coordination number can be adjusted to 3.0 or more and less than 5.0 through the concentration step S22. Since the coordination number can be reduced, generation of the above-described leakage current can be effectively suppressed.

Preferably, the second temperature is lower than 150°C. When the second temperature is higher than 150°C, elimination of ligands is accelerated, and the coordination number becomes too small. For example, the coordination number is 3 or less, or about 1 or 2. In this case, the viscosity of the precursor solution using the dispersion liquid containing niobium 2-ethylhexanoate excessively increases, and thus it may be difficult to uniformly form the above-described precursor film.

In the concentration step S22, the concentration is preferably performed until the coordination number of 2-ethylhexanoic acid coordinated to niobium becomes 3.0 or more and 5.0 or less. When the coordination number is 3.0 or more and 5.0 or less, as compared with the case where the coordination number is out of the above range, the risk of generation of a leakage current can be reduced while reducing film formation defects.

Therefore, in the piezoelectric body production method, it is preferable to produce a piezoelectric body containing potassium sodium niobate (KNN) using niobium 2-ethylhexanoate in which the coordination number of 2-ethylhexanoic acid coordinated to niobium is 3.0 or more and less than 5.0, potassium 2-ethylhexanoate, and sodium 2-ethylhexanoate. By using the niobium 2-ethylhexanoate, potassium 2-ethylhexanoate, and sodium 2-ethylhexanoate, in the KNN piezoelectric body, the risk of generation of a leakage current can be reduced while reducing film formation defects.

Further, in the concentration step S22, the concentration is preferably performed until the coordination number of 2-ethylhexanoic acid coordinated to niobium becomes 3.6 or more and 4.4 or less. When the coordination number is 3.6 or more and 4.4 or less, as compared with the case where the coordination number is out of the above range, the risk of generation of a leakage current can be particularly effectively reduced while reducing film formation defects.

Therefore, in niobium 2-ethylhexanoate, the coordination number of 2-ethylhexanoic acid coordinated to niobium is particularly preferably 3.6 or more and 4.4 or less. When the coordination number is 3.6 or more and 4.4 or less, as compared with the case where the coordination number is out of the above range, the risk of generation of a leakage current can be particularly effectively reduced while reducing film formation defects.

Preferably, the first temperature is lower than 100°C. When the first temperature is 100°C or more, ligands may be partly eliminated from niobium 2-ethylhexanoate during the synthesis. As a result, the coordination number of the plurality of niobium 2-ethylhexanoate complexes is less likely to be constant, and a dispersion in which niobium 2-ethylhexanoate having a large coordination number and niobium 2-ethylhexanoate having a small coordination number are mixed may be produced. When the first temperature is lower than 100°C, the difference in coordination number between the niobium 2-ethylhexanoate complexes can be reduced. Therefore, a homogeneous KNN piezoelectric body is easily formed.

Further, the first temperature is preferably higher than 80°C. When the first temperature is 80°C or less, the reaction between 2-ethylhexanoic acid and the niobium compound is not suitably performed, and a large amount of unreacted raw materials may remain.

Further, as described above, it is preferable to further mix acetic acid anhydride in addition to 2-ethylhexanoic acid and the niobium compound in the synthesis step S21. In the synthesis step S21, acetic acid anhydride functions as a reactant for decomposing the by-products as described above. Therefore, by using acetic anhydride, a reaction in which the by-products inhibit the synthesis of niobium 2-ethylhexanoate can be prevented from being caused. Therefore, the reaction involved in the synthesis of niobium 2-ethylhexanoate can be suitably promoted.

2-Ethylhexanoic acid used in the synthesis preferably has 2 or more and 12 or less carbon atoms. When the number of carbon atoms is 2 or more and 12 or less, the synthesis reaction can be suitably performed as compared with the case where the number of carbon atoms is not 2 or more and 12 or less.

In addition, as described above, 2-ethylhexanoic acid is preferable, and a case of 2-ethylhexanoic acid is described in Examples, but another niobium fatty acid complex may be used.

### 2. Examples

An example of the niobium fatty acid complex production method and the piezoelectric body production method of the present disclosure will be described with reference to Examples and Comparative Examples.

### 1 Niobium Fatty Acid Complex Production Method in Examples and Comparative Examples

### 1-1 Synthesis Step

First, raw materials and the like were prepared. Specifically, 2-ethylhexanoic acid as an example of a fatty acid as a raw material, toluene as a solvent, and acetic anhydride as a reactant were prepared. Thereafter, a molecular sieve was added to the raw materials and the like, and a dehydrating and deoxidizing treatment was performed by a bubbling method in which a nitrogen gas was fed for 0.5 hours or more and 1.0 hours or less. Thereafter, in an argon atmosphere, 12.69 g 2-ethylhexanoic acid, 16 ml of toluene, and 8.98 g of acetic acid anhydride were weighed and put into a flask in this order, and 5.00 g of pentaethoxyniobium, which is an example of a niobium compound as a raw material, was then slowly added dropwise. A raw material solution was obtained thereby.

Next, the raw material solution was stirred at a first temperature for 5 hours under a nitrogen flow. Silicone oil was used as a heating medium. Through the above steps, niobium 2-ethylhexanoate as a niobium fatty acid complex was obtained.

### 1-2 Concentration Step

Niobium 2-ethylhexanoate was then concentrated under reduced pressure at a second temperature and, after gas generation was no longer observed, vacuum drying was further performed for 30 minutes. Silicone oil was used as a heating medium. Through this step, niobium 2-ethylhexanoate to be used for producing a piezoelectric body was obtained. After the concentration, the used solution was recovered in an argon atmosphere.

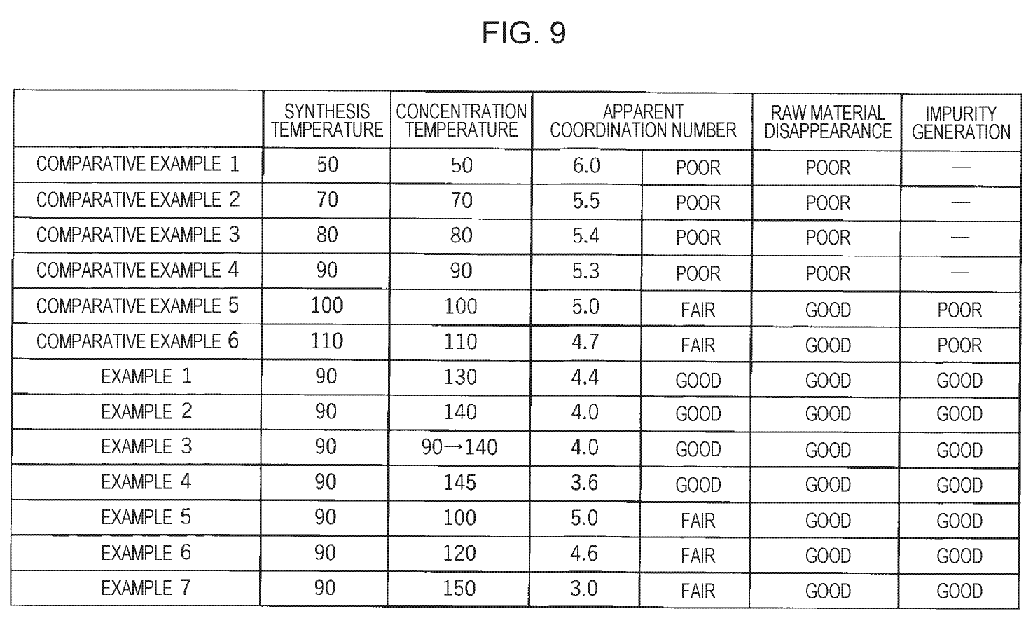

FIG. 9 is a table showing Examples and Comparative Examples. As shown in FIG. 9, in each of Examples and Comparative Examples, the first temperature and the second temperature were set as shown in the table. In Example 3, the concentration temperature was changed so as to increase from 90°C to 140°C in the middle.

The apparent coordination number shown in FIG. 9 is a coordination number obtained from the yield calculated based on the measurement result of NMR. The case where the apparent coordination number was more than 5 was evaluated as "poor," the case where the apparent coordination number was 3.0 or less or more than 4.5 and 5.0 or less was evaluated as "fair," and the case where the apparent coordination number was 3.6 or more and 4.4 or less was evaluated as "good."

The evaluation of raw material disappearance shown in FIG. 9 is an evaluation of the degree of disappearance of 2-ethylhexanoic acid as a raw material. A state in which the raw material disappeared or almost disappeared was evaluated as "good," a state in which the raw material did not disappear but was almost consumed was evaluated as "fair," and a state in which the amount of the raw material remaining was not small was evaluated as "poor."

The evaluation of impurity generation shown in FIG. 9 is also an evaluation showing the variation of ligands. The evaluation of impurity generation is an evaluation of the extent to which ligands having a coordination number different from that of the predominant ligands are present. The ligands having different coordination numbers correspond to impurities. For example, in the case where niobium 2-ethylhexanoate having four ligands is predominant, niobium 2-ethylhexanoate having a coordination number other than four corresponds to an impurity A state of low impurity was evaluated as "good," a state of high impurity was evaluated as "poor," and a state with an impurity ratio between "good" and "poor" was evaluated as "fair."

As shown in FIG. 9, in each Example, the second temperature is higher than the first temperature. That is, in each Example, synthesis is performed at a relatively low first temperature, and concentration is performed under reduced pressure at a second temperature higher than the first temperature. On the other hand, in each Comparative Example, the first temperature and the second temperature are the same. In each Example, there is no evaluation item rated as "poor." According to each Example, niobium 2-ethylhexanoate having a coordination number suitable for use in a precursor solution of a KNN piezoelectric body can be produced, and variation in the coordination number can be reduced, as compared with each Comparative Example.

On the other hand, in Comparative Examples, the second temperature is the same as the first temperature. In this case, favorable results could not be obtained in any of the evaluations of the apparent coordination number, raw material disappearance, and impurity generation. As in Examples 5 and 6, when the synthesis was performed at a high temperature of 100°C or more in the synthesis step, the variation in the coordination numbers was increased, and the evaluation of impurities was "poor." In Comparative Examples 1 to 4, the temperature in the synthesis step and the concentration step is 90°C or less, and 2-ethylhexanoic acid which is an unreacted raw material remains. In addition, the apparent coordination number tends to be higher in Comparative Examples 1 to 4 than in Examples. This is considered to be because the coordination number of 2-ethylhexanoic acid coordinated to actual niobium is not large, and the above-described unreacted 2-ethylhexanoic acid is taken into account because the apparent coordination number is evaluated from the yield. As described above, since unreacted 2-ethylhexanoic acid remained in each of Comparative Examples 1 to 4, the extent of generation of impurities was not evaluated.

In Comparative Examples 5 and 6, 2-ethylhexanoic acid, which is an unreacted raw material, does not remain. Therefore, the apparent coordination number is considered to be the coordination number of 2-ethylhexanoic acid coordinated to actual niobium. However, in Comparative Examples 5 and 6, since the temperature was set to 100°C or more from the time of synthesis, niobium 2-ethylhexanoate having a different coordination number was randomly mixed in each region such that tetra-coordinated niobium 2-ethylhexanoate was mainly present in a certain region and penta-coordinated niobium 2-ethylhexanoate was mainly present in another region. Therefore, when viewed partially, there is a region in which penta-coordinate niobium 2-ethylhexanoate is a main component, and this has been a factor of generating a leakage current.

On the other hand, in each Example, the coordination number is 3.0 or more and 5.0 or less. When the coordination number was within the above range, there was no evaluation result of "poor" in all of the evaluations of the apparent coordination number, raw material disappearance, and impurity generation. Further, in each Example, since the apparent coordination number was 3.0 or more and 5.0 or less, in the KNN piezoelectric body produced using each Example, significant generation of film formation defects and leakage current was not observed. In Examples 1, 5, and 6, the apparent coordination number exceeded 4.0, and thus it is considered that niobium 2-ethylhexanoate having five ligands was partially present. However, since niobium 2-ethylhexanoate having five ligands was not locally concentrated as in Comparative Examples 5 and 6, a large leakage current was not generated.

Furthermore, in Examples 1 to 4, the coordination number of 2-ethylhexanoic acid coordinated to niobium is 3.6 or more and 4.4 or less. When the coordination number was within the above range, favorable results could be obtained in all of the evaluations of the apparent coordination number, raw material disappearance, and impurity generation. In addition, in Examples 1 to 4, since the apparent coordination number was 3.6 or more and 4.4 or less, in the KNN piezoelectric bodies produced using Examples 1 to 4, generation of film formation defects and leakage current was not observed.

In Examples 1 to 4, 6, and 7, the second temperature is higher than 100°C. In Examples 1 to 4, 6, and 7, the coordination number is less than 5. Therefore, a leakage current was less likely to be generated.

In Examples 1 to 4 and 7, the second temperature is higher than 120°C. In Examples 1 to 4 and 7, the coordination number is 4.4 or less. Therefore, a leakage current was particularly less likely to be generated.

In Examples 1 to 7, the second temperature is 150°C or less. In Examples 1 to 7, the coordination number is 3.0 or more. Therefore, an excessive decrease in the coordination number is suppressed. Therefore, the viscosity of the precursor solution containing niobium 2-ethylhexanoate did not excessively increase, and the precursor solution was easy to handle. Therefore, the KNN piezoelectric body could be uniformly formed.

Further, in each Example, the first temperature is lower than 100°C. Therefore, niobium 2-ethylhexanoate having a high coordination number could be produced, and variation in the coordination number of niobium 2-ethylhexanoate in the dispersion liquid could be reduced.

Further, in each Example, the first temperature is higher than 80°C. Therefore, the evaluation of raw material disappearance was "good," and a large amount of unreacted raw material in the synthesis reaction did not remain.

### 3. Modification Example

The embodiments described above may be modified in various ways. A specific modification aspect that can be applied to the embodiments described above will be described below. Any two or more aspects selected from the following examples can be combined as appropriate as long as there is no contradiction.

The "liquid ejection head" may be a circulation type head having a so-called circulation flow path.

The "liquid ejection device" can be adopted in various devices, such as a facsimile machine and a copying machine, in addition to a device dedicated to printing. Use of the liquid ejection device is not limited to printing. For example, a liquid ejection device that ejects a solution of a coloring material is used as a manufacturing apparatus that forms a color filter of a display device such as a liquid crystal display panel. In addition, a liquid ejection device that ejects a solution of a conductive material is used as a manufacturing apparatus for forming an electrode and wiring on a wiring substrate. In addition, a liquid ejection device that ejects a solution of an organic substance related to a living body is used as a manufacturing apparatus for manufacturing a biochip, for example.

The piezoelectric element according to the present disclosure is not limited to the liquid ejection head or the liquid ejection device, and may be a device which generates a mechanical force when a voltage is applied, generates a voltage when a mechanical force is applied, or has a function of converting between voltage and mechanical force. The piezoelectric element according to the present disclosure may be, for example, an ultrasonic motor, a vibration-type dust removing device, a piezoelectric transformer, a piezoelectric speaker, a piezoelectric pump, an ultrasonic detector, an angular velocity sensor, an acceleration sensor, a vibration sensor, an inclination sensor, a pressure sensor, a collision sensor, a human detecting sensor, an infrared sensor, a terahertz sensor, a heat detection sensor, a pyroelectric sensor, a piezoelectric sensor, a ferroelectric memory (FeRAM), a ferroelectric transistor (FeFET), a ferroelectric arithmetic circuit (FeLogic), a ferroelectric capacitor, a wavelength converter, an optical waveguide, an optical path modulator, a refractive index control element, or an electronic shutter mechanism.

Although the present disclosure is described above based on the preferred embodiments, the present disclosure is not limited to the above-described embodiments. In addition, the configuration of each member of the present disclosure can be replaced with any configuration having the same function in the above-described embodiments, and any configuration can be added.

What is claimed is:

1. A niobium fatty acid complex production method, comprising:
a synthesis step of mixing a fatty acid and a niobium compound to synthesize a niobium fatty acid complex at a first temperature; and
a concentration step of concentrating the niobium fatty acid complex under reduced pressure at a second temperature higher than the first temperature.

2. The niobium fatty acid complex production method according to claim 1, wherein the second temperature is higher than 100°C.

3. The niobium fatty acid complex production method according to claim 2, wherein the second temperature is higher than 120°C.

4. The niobium fatty acid complex production method according to claim 1, wherein the second temperature is 150°C or less.

5. The niobium fatty acid complex production method according to claim 1, wherein the first temperature is lower than 100°C.

6. The niobium fatty acid complex production method according to claim 5, wherein the first temperature is higher than 80°C.

7. The niobium fatty acid complex production method according to claim 1, wherein acetic anhydride is further mixed in the synthesis step.

8. The niobium fatty acid complex production method according to claim 1, wherein in the concentration step, concentration is performed until a coordination number of fatty acids coordinated to niobium becomes 3.0 or more and 5.0 or less.

9. The niobium fatty acid complex production method according to claim 1, wherein in the concentration step, concentration is performed until a coordination number of fatty acids coordinated to niobium becomes 3.6 or more and 4.4 or less.

10. The niobium fatty acid complex production method according to claim 1, wherein the fatty acid has 2 or more and 12 or less carbon atoms.

11. The niobium fatty acid complex production method according to claim 10, wherein
the fatty acid is 2-ethylhexanoic acid; and
the niobium fatty acid complex is niobium 2-ethylhexanoate.

12. A piezoelectric body production method, comprising: producing a piezoelectric body containing potassium sodium niobate by using the niobium fatty acid complex produced by the production method according to claim 1, a potassium fatty acid complex, and a sodium fatty acid complex.

13. A piezoelectric body production method, comprising: producing a piezoelectric body containing potassium sodium niobate by using a niobium fatty acid complex in which a coordination number of fatty acids coordinated to niobium is 3.0 or more and 5.0 or less, a potassium fatty acid complex, and a sodium fatty acid complex.

14. The piezoelectric body production method according to claim 13, wherein the niobium fatty acid complex has a coordination number of fatty acids coordinated to niobium of 3.6 or more and 4.4 or less.
